(19) United States
(12) Patent Application Publication
(10) Pub. No.: US 2025/0331184 A1
(43) Pub. Date: Oct. 23, 2025

(54) MEMORY DEVICE AND METHOD OF FABRICATING THE SAME

(71) Applicant: MACRONIX International Co., Ltd., Hsinchu (TW)

(72) Inventors: Kuan-Wei Wu, Hsinchu County (TW); Yao-Wen Chang, Hsinchu County (TW); I-Chen Yang, Miaoli County (TW)

(73) Assignee: MACRONIX International Co., Ltd., Hsinchu (TW)

(21) Appl. No.: 18/642,831

(22) Filed: Apr. 23, 2024

(51) Int. Cl. H10B 43/35; H01L 23/528; H01L 23/532; H10B 43/27

(52) U.S. Cl. CPC H10B 43/35; H01L 23/5283; H01L 23/53295; H10B 43/27

(57) ABSTRACT

A memory device includes a composite stacked structure, a channel pillar, charge storage units, a tunneling layer, and at least one blocking layer. A first stacked structure includes insulating layers and conductive layers stacked alternately over a first region. A second stacked structure includes the insulating layers and intermediate layers alternately stacked over a second region. The charge storage units are embedded in the first stacked structure, and is located between the channel pillar and the conductive layers. The at least one blocking layer is disposed between the charge storage units and the conductive layers. A thickness of one of the plurality of the charge storage units is greater than a thickness of a corresponding conductive layer. The memory device is applicable to 3D NAND flash memory to create memory devices with high capacity and performance.

### BACKGROUND

### Technical Field

The embodiments of the disclosure relate to a semiconductor device and a method of fabricating the same, and particularly, to a memory device and a method of fabricating the same.

### Related Art

A non-volatile memory has the advantage that stored data does not disappear at power-off, so it becomes widely used for a personal computer or other electronic equipment. Currently, the three-dimensional (3D) memory commonly used in the industry includes a NOR memory and a NAND memory. In addition, another type of 3D memory is an AND memory, which can be applied to a multi-dimensional memory array with high integration and high area utilization, and has an advantage of a high operation speed. Therefore, the development of a 3D memory device has gradually become the current trend. However, 3D memory devices face issues such as interference between word lines and insufficient programming capabilities.

### SUMMARY

The embodiments of the disclosure provide a memory device and a method of fabricating the same, capable of reducing or avoiding interference between word lines and effectively enhancing the programming capability of the memory device.

An embodiment of the disclosure provides a memory device including a composite stacked structure, a channel pillar, a plurality of charge storage units, a tunneling layer, and at least one blocking layer. The composite stacked structure includes a first stacked structure and a second stacked structure. The first stacked structure includes a plurality of insulating layers and a plurality of conductive layers stacked alternately with each other, and is over a first region. The second stacked structure includes the plurality of insulating layers and a plurality of intermediate layers stacked alternately with each other, and is over a second region. The channel pillar extends through the first stacked structure. The plurality of charge storage units are embedded in the first stacked structure and located between the channel pillar and the plurality of conductive layers. The tunneling layer is disposed between the channel pillar and the plurality of charge storage units. The at least one of blocking layer is disposed between the plurality of charge storage units and the plurality of conductive layers. A thickness of one of the plurality of the charge storage units is greater than a thickness of a corresponding conductive layer.

An embodiment of the disclosure provides a method of fabricating a memory device including steps below. A stacked structure is formed. The stacked structure includes a plurality of insulating layers and a plurality of intermediate layers stacked alternately with each other. An opening is formed in the stacked structure. The plurality of insulating layers exposed in the opening are laterally removed to form a plurality of recesses. A first blocking layer is formed on a sidewall of the opening and in the plurality of recesses. A plurality of charge storage units are filled into remaining spaces of the plurality of recesses. A tunneling layer and a channel pillar are formed on sidewalls of the first blocking layer and the plurality of charge storage units. Portions of the plurality of intermediate layers are removed to form a plurality of horizontal openings. A plurality of second blocking layers and a plurality of conductive layers are formed in the plurality of horizontal openings.

Based on the above, in the embodiments of the disclosure, since the plurality of charge storage units are separated from each other, interference between word lines can be reduced or avoided. Since the area of the charge storage unit is increased, the programming capability of the memory device can be effectively enhanced.

### BRIEF DESCRIPTION OF DRAWINGS

FIG. 1A to FIG. 1G are schematic cross-sectional views of a fabrication process of a memory device according to an embodiment of the disclosure.

FIG. 2 is a schematic partially enlarged view of FIG. 1G.

FIG. 3 is a schematic cross-sectional view of a memory device with a complementary metal-oxide-semiconductor (CMOS) under array (CMOS under array, CuA) structure according to an embodiment of the disclosure.

FIG. 4 is a schematic cross-sectional view of a memory device with a complementary metal-oxide-semiconductor (CMOS) bonding array (CMOS bonding array, CbA) structure according to an embodiment of the disclosure.

### DESCRIPTION OF EMBODIMENTS

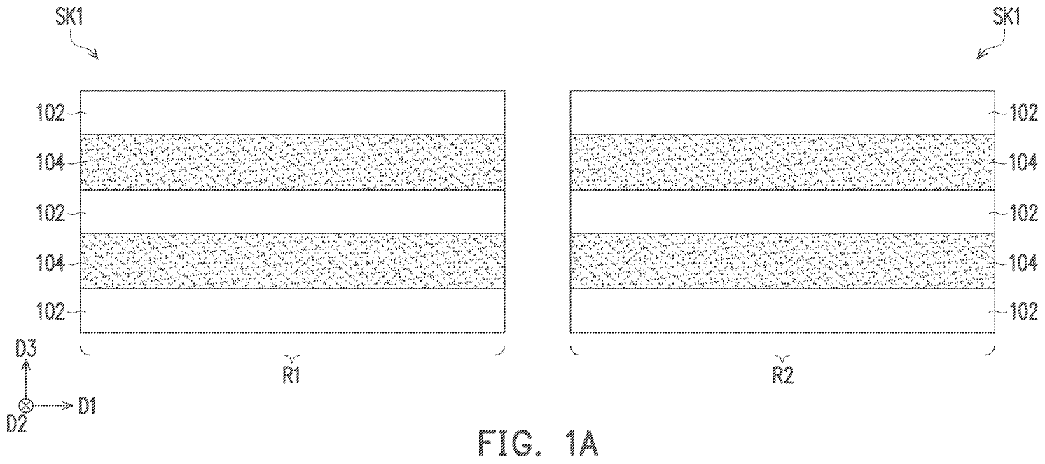

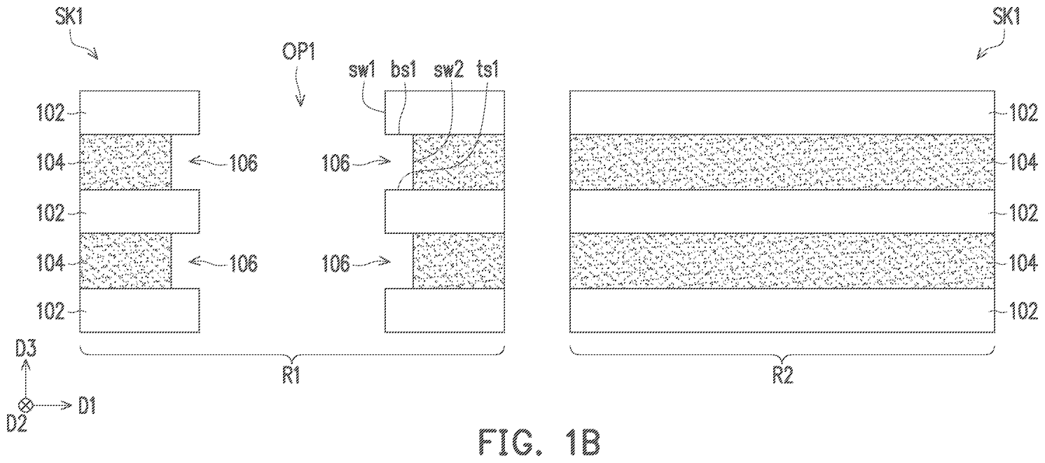

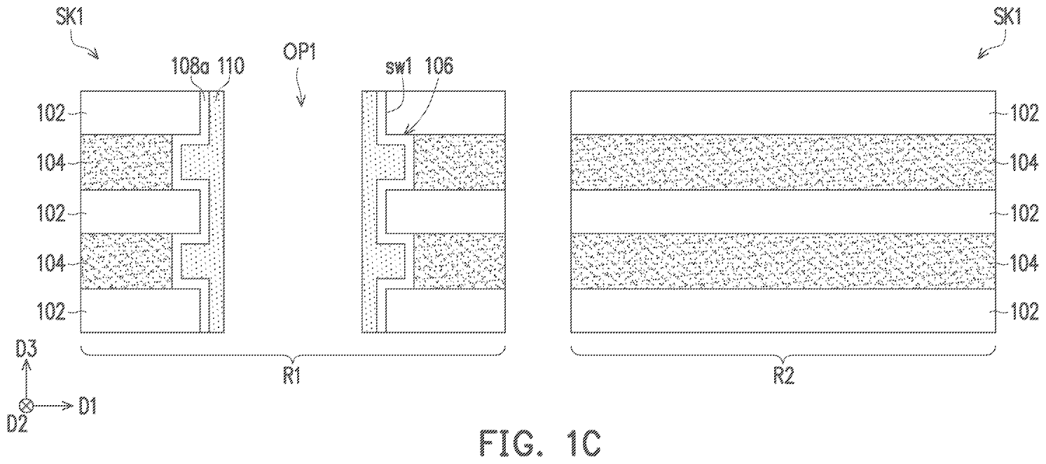

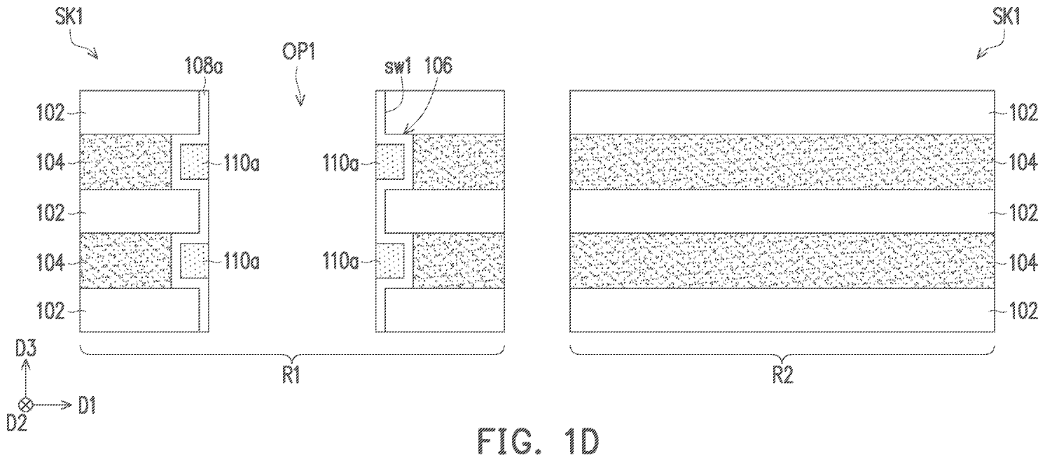

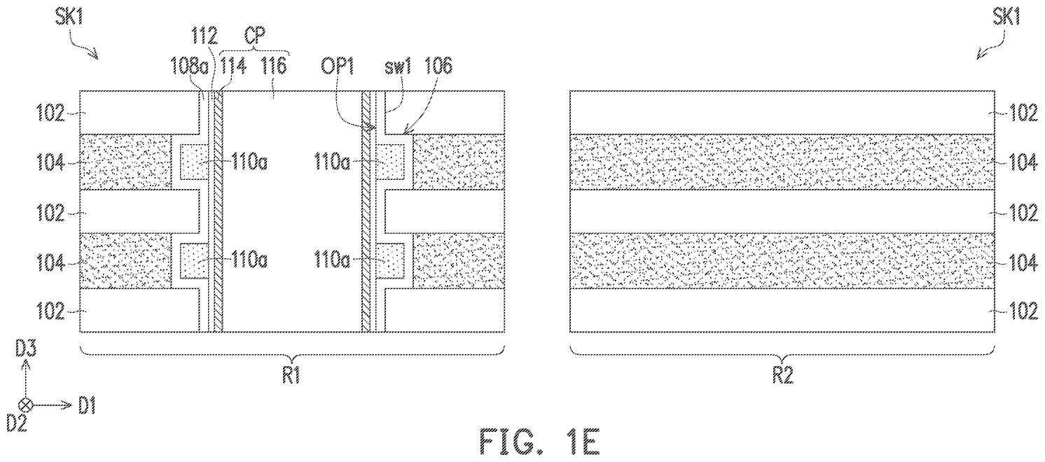

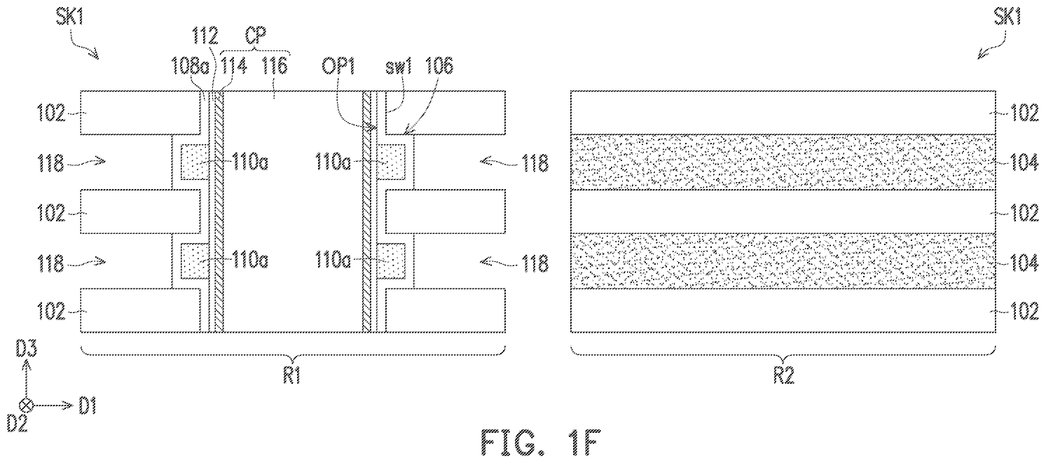

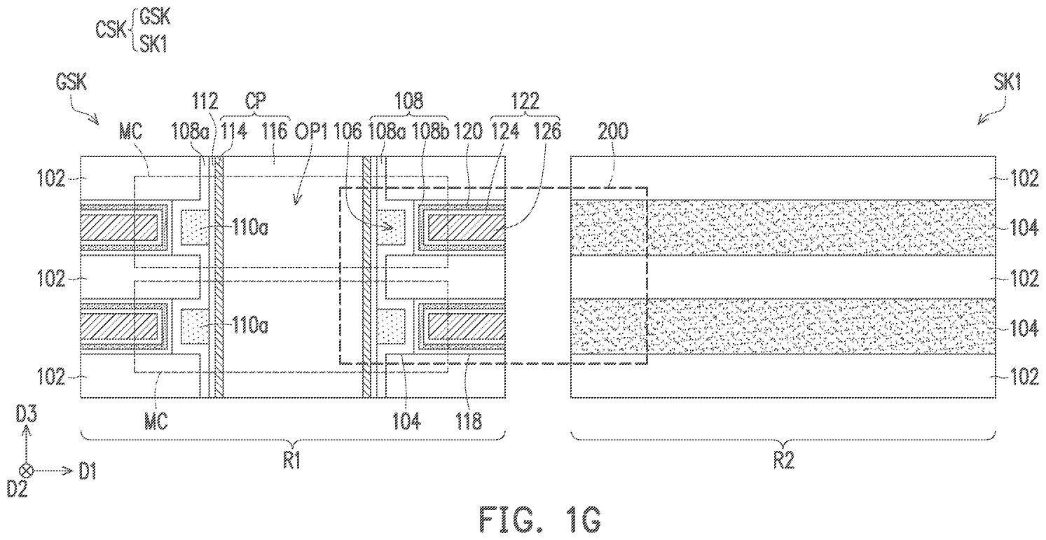

FIG. 1A to FIG. 1G are schematic cross-sectional views of a fabrication process of a memory device according to an embodiment of the disclosure.

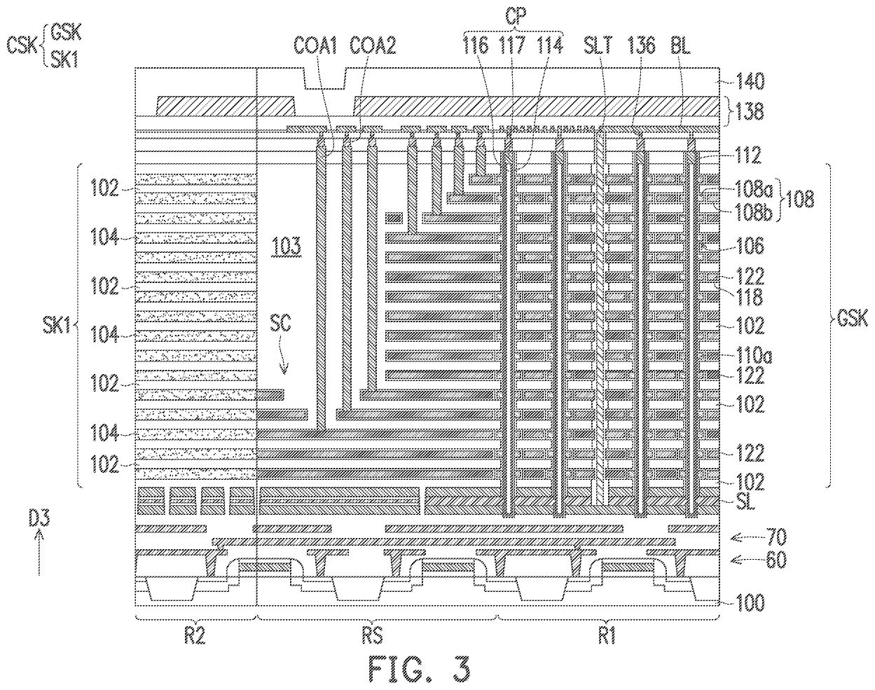

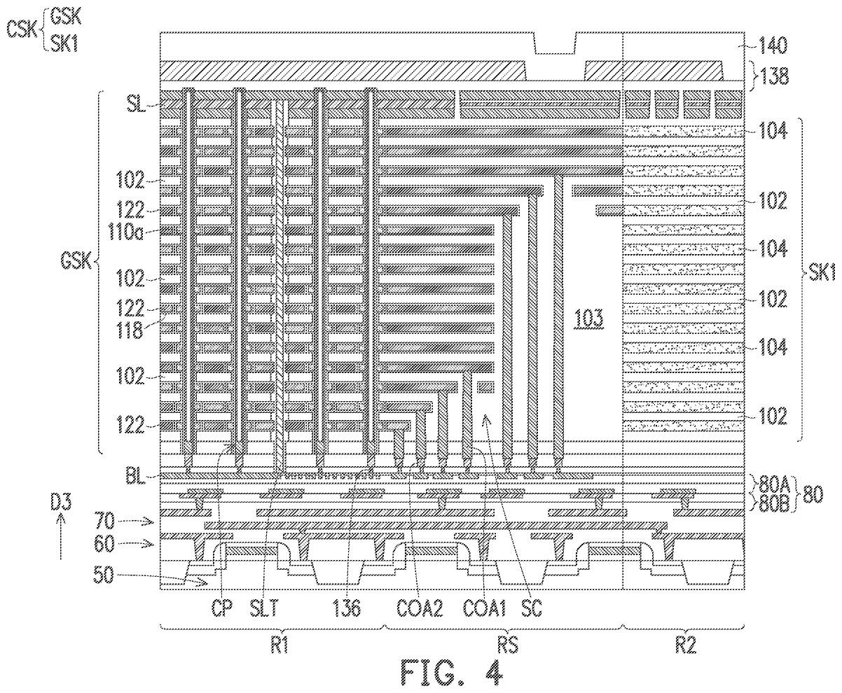

Referring to FIG. 1A, a stacked structure SK1 is formed. The stacked structure SK1 may also be referred to as an insulating stacked structure SK1. In this embodiment, the stacked structure SK1 includes insulating layers 102 and intermediate layers 104 alternately stacked with each other sequentially along a direction D3. The insulating layers 102 and the intermediate layers 104 extend along a direction D1 and a direction D2. The direction D3 is perpendicular to the direction D1 and the direction D2. The insulating layer 102 is, for example, a silicon oxide layer. The intermediate layer 104 is, for example, a silicon nitride layer. The intermediate layer 104 is partially removed in subsequent processes. FIG. 1A to FIG. 1G only show three insulating layers 102 and two intermediate layers 104. However, there may actually be more insulating layers 102 and more intermediate layers 104, as shown in FIG. 3 and FIG. 4.

At this stage, the stacked structure SK1 is formed in an array region R1, a staircase region RS (shown in FIG. 3), and a periphery region R2 of a substrate 100 similar to the figure shown in FIG. 3. However, a stacked structure GSK is not formed at this stage. The stacked structure GSK may be formed in the following processes to convert from a portion of the stacked structure SK1. A device layer 60, an interconnect structure 70, and a source line layer SL may be further formed between the substrate 100 and the stacked structure SK1. The device layer 60 may include complementary metal-oxide-semiconductor (CMOS) devices. In other embodiments, the stacked structure SK1 is formed on the substrate 100, and the device layer 60, the interconnect structure 70, and the source line layer SL are not further included between the substrate 100 and the stacked structure SK1.

Next, referring to FIG. 1B, photolithography and etching processes are performed to form an opening OP1 in the array region R1 of the stacked structure SK1. The etching process may be a dry etching process, a wet etching process, or a combination thereof. The opening OP1 penetrates through the stacked structure SK1 and may further extend to a layer below (not shown). The opening OP1 is, for example, a hole. In this embodiment, in a top view, the opening OP1 has a circular profile (not shown), but the disclosure is not limited thereto.

Then, portions of the plurality of intermediate layers 104 exposed in the opening OP1 are laterally removed to form a plurality of recesses 106. The recess 106 is composed of a sidewall sw2 of the intermediate layer 104, a bottom surface bs1 of an upper insulating layer 102 adjacent to the intermediate layer 104, and a top surface ts1 of a lower insulating layer 102 adjacent to the intermediate layer 104. With the formation of the recess 106, the sidewall sw2 of the intermediate layer 104 exposed by the opening OP1 is not aligned with a sidewall sw1 of the exposed insulating layer 102.

Referring to FIG. 1C, a first blocking layer 108a and a charge storage layer 110 are formed in the opening OP1. The first blocking layer 108a covers the sidewalls sw1 of the plurality of insulating layers 102 and is filled into the plurality of recesses 106. The first blocking layer 108a may be a conformal layer. The first blocking layer 108a is, for example, silicon oxide. The charge storage layer 110 is, for example, silicon nitride or other materials capable of trapping charges or storing charges. The charge storage layer 110 is filled in the remaining spaces of the recesses 106 and extends to cover the sidewall of the first blocking layer 108a on the sidewalls sw1 of the plurality of insulating layers 102.

Referring to FIG. 1D, afterwards, an etch-back process is performed to remove the charge storage layer 110 outside the plurality of recesses 106, such that the first blocking layer 108a covered on the sidewalls sw1 of the plurality of insulating layers 102 is exposed. Hence, a plurality of charge storage units 110a remaining in the plurality of recesses 106 are formed and separated from each other in the array region R1 of the stacked structure SK1.

Referring to FIG. 1E and FIG. 3, a tunneling layer 112, a channel layer 114, an insulating pillar 116, and a channel plug 117 (shown in FIG. 3) are formed in the opening OP1. The tunneling layer 112 can include a silicon oxide, a silicon oxynitride/silicon oxide, or a silicon oxide/silicon nitride combination (e.g. oxide/nitride/oxide). The channel layer 114 is, for example, polysilicon. The insulating pillar 116 is, for example, silicon oxide. The channel plug 117 is, for example, polysilicon. The tunneling layer 112 is located between the first blocking layer 108a and the channel layer 114, and between the charge storage unit 110a and the channel layer 114. The channel layer 114 is located between the tunneling layer 112 and the insulating pillar 116. The tunneling layer 112 and the channel layer 114 are respectively conformal layers, for example. The first blocking layer 108a, the tunneling layer 112, and the channel layer 114 do not fully fill the opening OP1. The channel plug 117 is located above the insulating pillar 116. The channel plug 117 and the insulating pillar 116 fully fill the remaining space in the opening OP1. The channel plug 117, the insulating pillar 116, and the channel layer 114 may be collectively referred to as a channel pillar CP (shown in FIG. 3).

Referring to FIG. 1F, next, a gate replacement process is performed the stacked structure SK1 in the array region R1. First, an etching process such as a wet etching process is performed to remove the plurality of intermediate layers 104 and form a plurality of horizontal openings 118. The opening 118 exposes the sidewall of the first blocking layer 108a and the upper and lower surfaces of the insulating layer 102.

Subsequently, referring to FIG. 1G, a second blocking layer 108b, a high dielectric constant (high-k) dielectric layer 120, and a conductive layer 122 are formed in the horizontal opening 118. The material of the second blocking layer 108b may be the same as the material of the first blocking layer 108a and may be, for example, silicon oxide. The high-k dielectric layer 120 includes a dielectric material with a dielectric constant greater than 3.9 or even greater than 7. The high-k dielectric layer 120 is, for example, aluminum oxide (Al₂O₃), hafnium oxide (HfO₂), lanthanum oxide (La₂O₅), transition metal oxides, lanthanide element oxides, or a combination thereof. The conductive layer 122 may include a barrier layer 124 and a metal layer 126. The material of the barrier layer 124 is, for example, titanium (Ti), titanium nitride (TiN), tantalum (Ta), tantalum nitride (TaN), or a combination thereof. The metal layer 126 is, for example, tungsten, cobalt, or ruthenium. A formation method of the high-k dielectric layer 120, the barrier layer 124, and the metal layer 126 includes, for example, sequentially forming a high-k material, a barrier material, and a conductive material in the horizontal opening 118, and performing an etch-back process to form the high-k dielectric layer 120, the barrier layer 124, and the metal layer 126 in the plurality of horizontal openings 118. At this time, a stacked structure GSK has been formed in the array region R1. The stacked structure GSK includes a memory array composed of a plurality of memory cells MC. Each memory cell MC is formed by the channel layer 114, the tunneling layer 112, the charge storage unit 110a, the blocking layer 108 (the first blocking layer 108a and second blocking layer 108b) and the conductive layer 122. The insulating layers 102 and the intermediate layers 104 of the stacked structure SK1 in the periphery region R2 are not removed and alternate with each other. The stacked structure GSK and the stacked structure SK1 are collectively referred to as a composite stacked structure CSK.

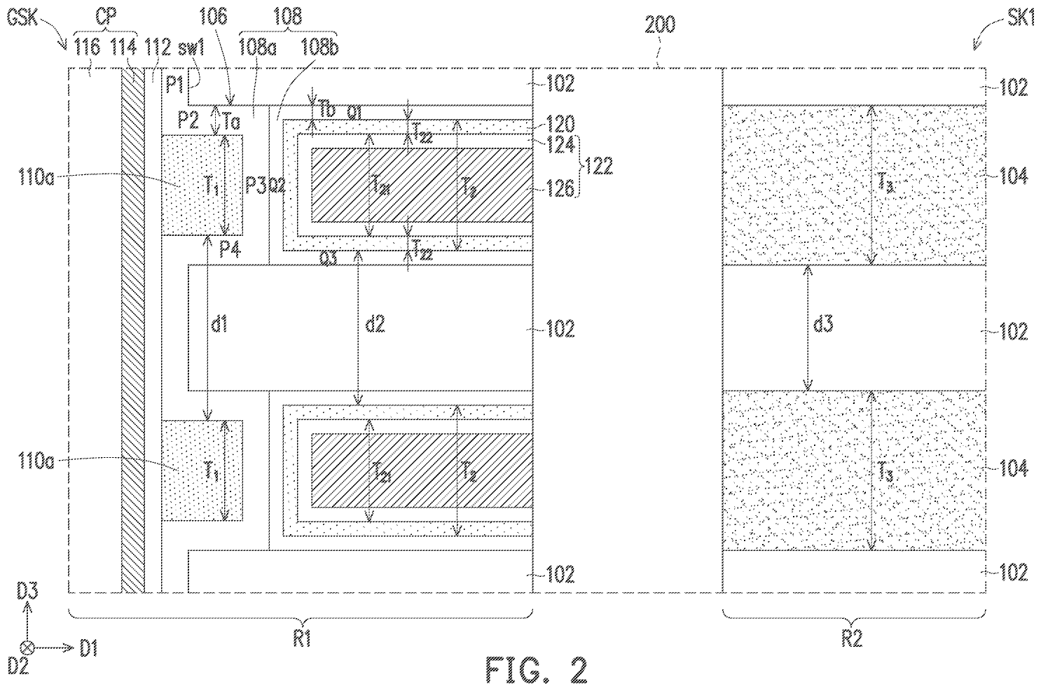

FIG. 2 is a partially enlarged view of a region 200 in FIG. 1G.

Referring to FIG. 2, the memory device of the region 200 of at least one embodiment of the disclosure includes the composite stacked structure CSK, the channel pillar CP, the tunneling layer 112, the plurality of charge storage units 110a, and a blocking layer 108. In the embodiment of the disclosure, the blocking layer 108 includes the first blocking layer 108a and the plurality of second blocking layers 108b.

The composite stacked structure CSK includes the stacked structure GSK and the stacked structure SK1. The stacked structure GSK is located in the array region R1. The stacked structure GSK includes the plurality of insulating layers 102 and the plurality of conductive layers (word line layers) 122 stacked alternately with each other. The conductive layer 122 may include the barrier layer 124 and the metal layer 126. In some embodiments, the memory device further includes a plurality of high-k dielectric layers 120. Each of the plurality of high-k dielectric layers 120 is disposed between the blocking layer 108 and each of the plurality of conductive layers 122.

The stacked structure SK1 is located in the periphery region R2. The stacked structure SK1 includes the plurality of insulating layers 102 and the plurality of intermediate layers 104 stacked alternately with each other. Each of the plurality of intermediate layers 104 of the stacked structure SK1 and each of the plurality of conductive layers 122 of stacked structure GSK are disposed at a corresponding level in the periphery region R2 and the array region R1. Therefore, a corresponding conductive layer 122 is present with respect to an intermediate layer 104 at a specific height. Similarly, a corresponding intermediate layer 104 is present with respect to a conductive layer 122 at a specific height.

The channel pillar CP and the tunneling layer 112 extend continuously in the direction D3 and penetrate through the stacked structure GSK. The tunneling layer 112 is disposed between the channel pillar CP and the plurality of charge storage units 110a.

The plurality of charge storage units 110a are embedded in the recesses 106 of the stacked structure GSK and are adjacent to the plurality of conductive layers 122. The plurality of charge storage units 110a are surrounded by the tunneling layer 112 and the first blocking layer 108a. More specifically, in the direction D1, the plurality of charge storage units 110a are located between the channel pillar CP and the plurality of conductive layers 122. More specifically, in the direction D1, the plurality of charge storage units 110a are located between the tunneling layer 112 and the first blocking layer 108a. In the direction D3, the plurality of charge storage units 110a are separated from each other by the insulating layer 102 and the first blocking layer 108a. In other words, the plurality of charge storage units 110a are discontinuous and separated from each other in the direction D3.

The first blocking layer 108a of the blocking layer 108 extends continuously in the direction D3 and has a concave-convex profile. The first blocking layer 108a includes a plurality of portions P1, P2, P3, and P4. The portion P1 is disposed on the sidewall sw1 of the plurality of insulating layers 102. The portion P1 is disposed between the plurality of insulating layers 102 and the tunneling layer 112 and is in contact with the plurality of insulating layers 102 and the tunneling layer 112. The portions P2, P4, and P3 are disposed on the sidewalls and the bottom of the recess 106. The portions P2 and P4 are disposed between the plurality of insulating layers 102 and the plurality of charge storage units 110a and are in contact with the plurality of insulating layers 102 and the plurality of charge storage layers 110. The portion P3 is disposed between the charge storage unit 110a and the plurality of conductive layers 122. More specifically, the portion P3 is disposed between the charge storage unit 110a and the second blocking layer 108b and is in contact with the charge storage unit 110a and the second blocking layer 108b. The plurality of second blocking layers 108b of the blocking layer 108 include portions Q1, Q2, and Q3. The portions Q1 and Q3 are disposed between the plurality of insulating layers 102 and the conductive layer 122. The portion Q2 is disposed between the portion P3 of the first blocking layer 108a and the conductive layer 122.

In the embodiment of the disclosure, a thickness Ta of the first blocking layer 108a is greater than a thickness Tb of the corresponding second blocking layer 108b. That is, Ta>Tb. A thickness Ta+Tb of the blocking layer 108 (i.e., a combined layer including the first blocking layer 108a and the second blocking layer 108b) between the charge storage unit 110a and the conductive layer 122 is greater than the thickness Ta of the first blocking layer 108a above and below the charge storage unit 110a, and is greater than the thickness Tb of the second blocking layer 108b above and below the conductive layer 122. That is, Ta+Tb>Ta>Tb.

In the embodiment of the disclosure, a thickness T₁ of the charge storage unit 110a is less than a sum (i.e., a thickness T₂) of a thickness T₂₁ of the corresponding conductive layer 122 and twice a thickness T₂₂ of the corresponding high-k dielectric layer 120. That is, T₂=T₂₁+2×T₂₂, and T₁<T₂. The thickness T₁ of the charge storage unit 110a is greater than the thickness T₂₁ of the corresponding conductive layer 122. That is, T₁>T₂₁. In some embodiments, a difference between T₁ and T₂₁ is approximately 50 angstroms to 100 angstroms. Since the thickness T₁ of the charge storage unit 110a is increased, the area of the charge storage unit 110a can be increased, thereby effectively enhancing the programming capability of the memory device.

In the embodiment of the disclosure, a thickness T₃ of the intermediate layer 104 is greater than the thickness T₁ of the corresponding charge storage unit 110a. That is, T₃>T₁. The thickness T₃ of the intermediate layer 104 is greater than the sum (i.e., the thickness T₂) of the thickness T₂₁ of the corresponding conductive layer 122 and twice the thickness T₂₂ of the corresponding high-k dielectric layer 120. That is, T₂=T₂₁+2×T₂₂, and T₃>T₂. In some embodiments, a ratio (T₂/T₃) of the thickness T₂ to the thickness T₃ is 0.7 to 0.8. Since T₂>T₁, T₃>T₂>T₁.

A first distance d1 between two adjacent charge storage units 110a is greater than a second distance d2 between two adjacent high-k dielectric layers 120. The second distance d2 is greater than a third distance d3 between two adjacent intermediate layers 104. That is, d1>d2>d3.

In the embodiment of the disclosure, since the plurality of charge storage units 110a are separated from each other, interference between word line layers (conductive layers 122) can be reduced or avoided. Furthermore, in the embodiment of the disclosure, the blocking layer 108 is divided into two layers, and since the first blocking layer 108a and the second blocking layer 108b each contribute a portion of the thickness, the combined blocking layer 108 can have the required thickness (Ta+Tb) to isolate the plurality of charge storage units 110a and the plurality of conductive layers 122. The first blocking layer 108a is formed in the recess 106 and is covered around the charge storage unit 110a. The second blocking layer 108b is covered around the conductive layer 122. Since the blocking layer 108 having the required thickness (Ta+Tb) is not formed in the entire recess 106, the height and the space for forming the charge storage unit 110a can be increased in the recess 106. Since the height of the charge storage unit 110a is increased, the area of the charge storage unit 110a is increased, thereby effectively enhancing the programming capability of the memory device.

The composite stacked structure CSK described above may be applied to a memory device with a complementary metal-oxide-semiconductor (CMOS) under array (CMOS under array, CuA) structure and a memory device with a complementary metal-oxide-semiconductor (CMOS) bonding array (CMOS bonding array, CbA) structure.

FIG. 3 is a schematic cross-sectional view of a memory device with a complementary metal-oxide-semiconductor (CMOS) under array (CuA) structure according to an embodiment of the disclosure.

Referring to FIG. 3, in some embodiments, as described above, a device layer 60, an interconnect structure 70, and a source line layer SL may be provided below the stacked structure (with the memory array) GSK of the disclosure and above the substrate 100. The device layer 60 may include complementary metal-oxide-semiconductor (CMOS) devices. In some embodiments, these complementary metal-oxide-semiconductor (CMOS) devices and the interconnect structure 70 may be formed before the formation of the stacked structure GSK and are thus located under the memory array, so this type is also referred to as a memory with a complementary metal-oxide-semiconductor (CMOS) under array (CuA) structure.

Referring to FIG. 3, in some embodiments, a staircase structure SC and a dielectric layer 103 are provided in the staircase region RS of the memory device. The staircase structure SC may be formed by patterning the stacked structure SK1 before forming the opening OP1 (shown in FIG. 1B). The dielectric layer 103 may be formed on the staircase structure SC after the formation of the staircase structure SC. The material of the dielectric layer 103 is, for example, silicon oxide. The dielectric layer 103 may be planarized by a planarization process such as a chemical-mechanical polishing process.

Referring to FIG. 3, in some embodiments, the memory device further includes a separation wall SLT. To form the separation wall SLT, before the formation of the horizontal opening 118 prior to the gate replacement process described above, photolithography and etching processes may be performed to form a slit trench (not shown) in the stacked structure SK1. Next, after the gate replacement process is performed, the separation wall SLT is formed in the slit trench. In a top view, the separation wall SLT has a strip shape (not shown). In some embodiments, the memory device further includes a plurality of conductive plugs COAL and a plurality of conductive plugs COA2 on the stacked structure GSK and the stacked structure SK1. Each of the plurality of conductive plugs COA1 connects the conductive layer 122 and the channel plug 117. Each of the plurality of conductive plugs COA2 connects the conductive plug COA1. In some embodiments, the memory device further includes a via 136, a bit line BL, an interconnect structure 138, a protective layer 140, etc.

FIG. 4 is a schematic cross-sectional view of a memory device with a complementary metal-oxide-semiconductor (CMOS) bonding array (CbA) structure according to an embodiment of the disclosure.

Referring to FIG. 4, in other embodiments, before the formation of the stacked structure GSK, a source line layer SL is formed on a first substrate (not shown). Afterwards, after forming the stacked structure SK1, the stacked structure GSK, the conductive plugs COAL and COA2, the via 136, and the bit line BL on the first substrate according to the method of the embodiments described above, a bonding layer 80A is formed. Then, a second substrate 50 including the device layer 60 and the interconnect structure 70 described above and a bonding layer 80B is provided. Next, the first substrate (not shown) is flipped. The bonding layer 80A and the bonding layer 80B are bonded together to form a bonding structure 80. The first substrate (not shown) may be completely removed or thinned (not shown) by polishing, and then an interconnect structure 138 and a protective layer 140 are formed above the stacked structure GSK. The second substrate 50, the device layer 60, the interconnect structure 70, and the bonding structure 80 are located below the stacked structure GSK. In this manner, the complementary metal-oxide-semiconductor device is formed under the memory array by bonding, so this type is also referred to as a complementary metal-oxide-semiconductor (CMOS) bonding array (CbA) structure.

Based on the above, in the memory device and the method of fabricating the same according to the embodiments of the disclosure, the plurality of charge storage layers of the plurality of memory cells can be separated from each other. Furthermore, the embodiments of the disclosure fabricate dual blocking layers following a dual-layer approach, with one of the blocking layers formed in the recess before the formation of the charge storage layer, and the other of the blocking layers formed in the gate replacement process. By controlling the thickness of the dual blocking layers, the height of the charge storage layer can be greater than the height of the word line layer (i.e., the conductive layer), so an improved operation window can be obtained.

What is claimed is:

1. A memory device, comprising:
a composite stacked structure, comprising:
a first stacked structure, comprising a plurality of insulating layers and a plurality of conductive layers stacked alternately, over a first region; and
a second stacked structure, comprising the plurality of insulating layers and a plurality of intermediate layers stacked alternately, over a second region;
a channel pillar, extending through the first stacked structure;
a plurality of charge storage units, embedded in the first stacked structure, and between the channel pillar and the plurality of conductive layers;
a tunneling layer, disposed between the channel pillar and the plurality of charge storage units; and
at least one blocking layer disposed between the plurality of charge storage units and the plurality of conductive layers,
wherein a thickness of one of the plurality of the charge storage units is greater than a thickness of a corresponding conductive layer.

2. The memory device according to claim 1, further comprising a plurality of high-k dielectric layers, disposed between the at least one blocking layer and the plurality of conductive layers.

3. The memory device according to claim 2, wherein the thickness of one of the plurality of charge storage units is less than a sum of the thickness of the corresponding conductive layer and twice a thickness of the corresponding high-k dielectric layer.

4. The memory device according to claim 2, wherein a thickness of one of the plurality of intermediate layers is greater than a sum of the thickness of the corresponding conductive layer and twice a thickness of the corresponding high-k dielectric layer.

5. The memory device according to claim 2, wherein a ratio of a sum of the thickness of one of the plurality of conductive layers and twice a thickness of the corresponding high-k dielectric layer to a thickness of the corresponding intermediate layer is 0.7 to 0.8.

6. The memory device according to claim 2, wherein a thickness of one of the plurality of intermediate layers is greater than the thickness of the corresponding charge storage unit.

7. The memory device according to claim 2, wherein a first distance between two adjacent charge storage units is greater than a second distance between two adjacent high-k dielectric layers.

8. The memory device according to claim 7, wherein the second distance is greater than a third distance between two adjacent intermediate layers.

9. The memory device according to claim 1, wherein the at least one blocking layer comprises a first blocking layer disposed between the plurality of storage layers and the plurality of conductive layers, and a plurality of second blocking layers disposed between the first blocking layer and the plurality of conductive layers.

10. The memory device according to claim 9, wherein a thickness of the first blocking layer is greater than a thickness of the corresponding second blocking layer.

11. A method of fabricating a memory device, comprising:
forming a stacked structure, wherein the stacked structure comprises a plurality of insulating layers and a plurality of intermediate layers stacked alternately with each other;
forming an opening in the stacked structure;
laterally removing the plurality of insulating layers exposed in the opening to form a plurality of recesses;
forming a first blocking layer on a sidewall of the opening and in the plurality of recesses;
filling a plurality of charge storage layers into remaining spaces of the plurality of recesses;
forming a tunneling layer and a channel pillar on sidewalls of the first blocking layer and the plurality of charge storage layers;
removing portions of the plurality of intermediate layers to form a plurality of horizontal openings; and
forming a plurality of second blocking layers and a plurality of conductive layers in the plurality of horizontal openings.

12. The method of fabricating a memory device according to claim 11, wherein the first blocking layer is thicker than one of the second blocking layers.

13. The method of fabricating a memory device according to claim 12, further comprising forming a plurality of high-k dielectric layers between the plurality of second blocking layers and the plurality of conductive layers.

14. The method of fabricating a memory device according to claim 13, wherein a thickness of one of the plurality of charge storage layers is less than a sum of a thickness of the corresponding conductive layer and twice a thickness of the corresponding high-k dielectric layer.

15. The method of fabricating a memory device according to claim 13, wherein a thickness of one of the plurality of charge storage layers is greater than a thickness of the corresponding conductive layer.

16. The method of fabricating a memory device according to claim 15, wherein a thickness of one of the plurality of intermediate layers is greater than a sum of a thickness of the corresponding conductive layer and twice a thickness of the corresponding high-k dielectric layer.

17. The method of fabricating a memory device according to claim 15, wherein a ratio of a sum of a thickness of one of the plurality of conductive layers and twice a thickness of the corresponding high-k dielectric layer to a thickness of the corresponding intermediate layer is 0.7 to 0.8.

18. The method of fabricating a memory device according to claim 15, wherein a thickness of one of the plurality of intermediate layers is greater than a thickness of the corresponding charge storage layer.

19. The method of fabricating a memory device according to claim 15, wherein a first distance between two adjacent charge storage layers is greater than a second distance between two adjacent high-k dielectric layers.

20. The method of fabricating a memory device according to claim 19, wherein the second distance is greater than a third distance between two adjacent intermediate layers.
